(19) United States
(12) Patent Application Publication
(10) Pub. No.: US 2017/0092774 A1
(43) Pub. Date: Mar. 30, 2017

(54) SEMICONDUCTOR MEMORY DEVICE AND METHOD OF MANUFACTURING THE SAME

(71) Applicant: Kabushiki Kaisha Toshiba, Minato-ku (JP)

(72) Inventor: Takeshi SAKAGUCHI, Yokkaichi (JP)

(73) Assignee: Kabushiki Kaisha Toshiba, Minato-ku (JP)

(21) Appl. No.: 15/003,904

(22) Filed: Jan. 22, 2016

Related U.S. Application Data
(60) Provisional application No. 62/232,844, filed on Sep. 25, 2015.

(51) Int. Cl. H01L 29/788; H01L 29/66

(52) U.S. Cl. CPC H01L 29/7883; H01L 29/66825

(57) ABSTRACT

A semiconductor memory device according to an embodiment includes a tunnel insulating layer arranged above a first semiconductor layer, a charge accumulation layer arranged above the tunnel insulating layer, a block insulating layer arranged above the charge accumulation layer, and a control gate arranged above the block insulating layer, wherein the charge accumulation layer includes a second semiconductor layer and a metal film arranged above the second semiconductor layer, and the second semiconductor layer includes a dividing film made of an insulator and a divided portion divided by the dividing film.

### CROSS-REFERENCE TO RELATED APPLICATIONS

This application is based upon and claims the benefit of priority from the prior U.S. Provisional Application 62/232,844, filed on Sep. 25, 2015, the entire contents of which are incorporated herein by reference.

### BACKGROUND

Technical Field

Embodiments of the present invention relates to a semiconductor memory device and a method of manufacturing the same.

Description of the Related Art

Flash memories that are ones of semiconductor memory devices include a transistor made of a semiconductor layer, a charge accumulation layer (floating gate), and a control gate, as a memory cell. The flash memories change a threshold voltage of the memory cell according to a charge accumulated in the charge accumulation layer, and store a plurality of different data according to the magnitude of the threshold voltage.

In recent years, in the flash memories, a memory cell having a so-called flat cell structure is sometimes used from a perspective of realization of high integration. However, in a case of a memory cell including the charge accumulation layer obtained by stacking a metal film on the semiconductor layer, and a block insulating layer formed immediately above the charge accumulation layer, of the memory cells having the flat cell structure, deterioration of a charge holding property of the memory cell due to diffusion of a metal film material to the block insulating layer is a problem.

### BRIEF DESCRIPTION OF THE DRAWINGS

FIG. 1 is a functional block diagram of a semiconductor memory device according to a first embodiment.

FIG. 2 is a circuit diagram of a part of a memory cell array of the semiconductor memory device according to the first embodiment.

FIG. 3 is a plan view of a part of the memory cell array of the semiconductor memory device according to the first embodiment.

FIG. 4 is a sectional view of a part of a memory cell array of a semiconductor memory device according to a comparative example of the first embodiment.

FIG. 5 is a diagram for describing a variation mechanism of a threshold voltage of the memory cell of the semiconductor memory device according to the comparative example.

FIG. 6 is a sectional view illustrating a part of the memory cell array of the semiconductor memory device according to the first embodiment.

FIGS. 7 to 13 are sectional views for describing a process of manufacturing a memory cell array of a semiconductor memory device according to the first embodiment.

FIG. 14 is a sectional view of a part of a memory cell array of a semiconductor memory device according to a second embodiment.

FIGS. 15 to 17 are sectional views for describing a process of manufacturing a memory cell array of a semiconductor memory device according to the second embodiment.

### DETAILED DESCRIPTION

A semiconductor memory device according to an embodiment includes: a tunnel insulating layer arranged above a first semiconductor layer; a charge accumulation layer arranged above the tunnel insulating layer; a block insulating layer arranged above the charge accumulation layer; and a control gate arranged above the block insulating layer, the charge accumulation layer including a second semiconductor layer, and a metal film arranged above the second semiconductor layer, and the second semiconductor layer including a dividing film made of an insulator, and a divided portion divided by the dividing film.

Hereinafter, a semiconductor memory device and a method of manufacturing the same according to embodiments will be described with reference to the drawings.

### First Embodiment

First, an overall configuration of a semiconductor memory device according to a first embodiment will be described. Note that, hereinafter, a NAND-type flash memory will be exemplarily described. However, the embodiment below is applicable to a NOR-type flash memory.

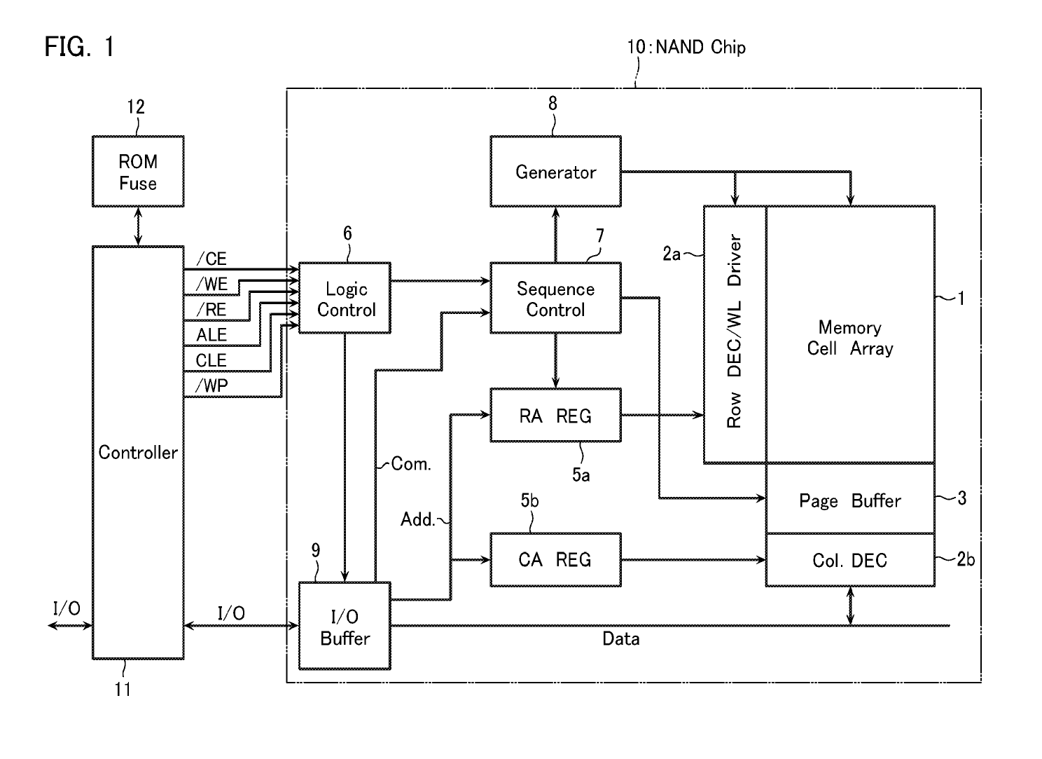

FIG. 1 is a diagram illustrating a functional block diagram of a semiconductor memory device according to the present embodiment.

This flash memory includes a NAND chip 10, a controller 11 that controls the NAND chip 10, and a ROM fuse 12 that stores various types of information necessary for an access to the NAND chip 10.

The NAND chip 10 includes a memory cell array 1. The memory cell array 1 includes a plurality of bit lines extending in a column direction, a plurality of word lines and source lines extending in a row direction, and a plurality of memory cells selected by the bit lines and the word lines. The memory cell array 1 will be described below in details.

Further, the NAND chip 10 includes a control unit that execute a read sequence that is a series of processing of reading data, and a write sequence that is a series of processing of writing data. The control unit includes a row decoder/word line driver 2a, a column decoder 2b, a page buffer 3, a row address register 5a, a column address register 5b, a logic control circuit 6, a sequence control circuit 7, a voltage generating circuit 8, and an I/O buffer 9.

The row decoder/word line driver 2a drives the word lines of the memory cell array 1 and a selection gate line described below. The page buffer 3 includes a sense amplifier circuit of one page and a data holding circuit. Read data of one page held in the page buffer 3 is sequentially column-selected by the column decoder 2b, and is output to an external I/O terminal through the I/O buffer 9. Write data supplied from an I/O terminal is selected by the column decoder 2b and is loaded to the page buffer 3. Write data of one page is loaded to the page buffer 3. Row and column address signals are input through the I/O buffer 9, and are respectively transferred to the row decoder 2a and the column decoder 2b. The row address register 5a holds an erasure block address in a case of erasure of data, and holds a page address in a case of reading and writing data. A head column address for loading write data before the start of the write sequence and a head column address for the read sequence are input to the column address register 5b. The column address register 5b holds the input column address until write enable/WE and read enable/RE are toggled with a predetermined condition.

The logic control circuit 6 controls an input of a command or an address and input/output of data, based on control signals such as a chip enable signal/CE, a command enable signal CLE, an address latch enable signal ALE, a write enable signal/WE, and a read enable signal/RE. A read operation or a write operation is executed with a command. Upon receiving the command, the sequence control circuit 7 performs sequence control of read, write, or erasure. The voltage generating circuit 8 is controlled by the sequence control circuit 7, and generates a predetermined voltage necessary for various operations.

The controller 11 controls the read sequence and the write sequence with a condition suitable for a current write state of the NAND chip 10. Note that a part of the read sequence and the write sequence can be controlled by the control unit of the NAND chip 10.

Next, a circuit of the memory cell array 1 will be described. Note that, hereinafter, the memory cell array 1 of the present embodiment will be written as memory cell array 100 to be distinguished from other embodiments and comparative examples.

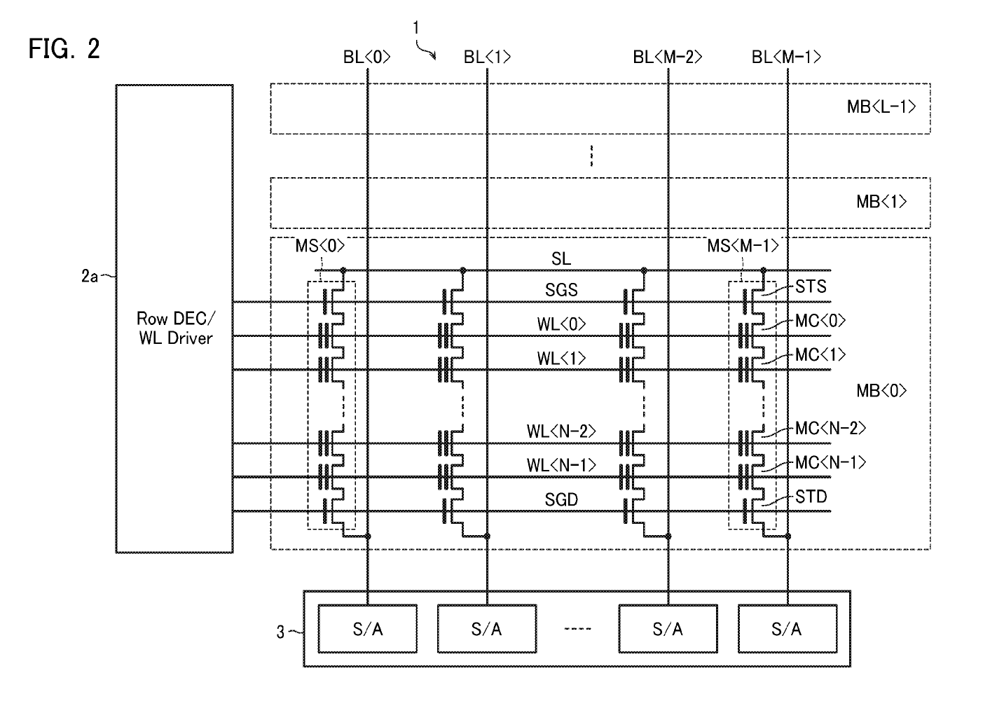

FIG. 2 is a circuit diagram of a part of a memory cell array of a semiconductor memory device according to an embodiment.

The memory cell array 100 includes a source line SL extending in the row direction, a source-side selection gate line SGS, N word lines WL<0> to <N−1>, a drain-side selection gate line SGD, M bit lines BL<0> to <M−1> extending in the column direction, and M memory strings MS<0> to <M−1>. Each memory string MS includes N memory cells MC<0> to <N−1> connected in series, and a source-side selection gate transistor STS and a drain-side selection gate transistor STD connected to both sides of the memory cells. Each memory cell MC is configured from a channel on a semiconductor substrate, a charge accumulation layer arranged above the channel, and a transistor including a control gate arranged above the charge accumulation layer.

A source of the source-side selection gate transistor STS is connected to the source line SL. A drain of the drain-side selection gate transistor STD is connected to one of the bit lines BL<0> to <M−1>. Control gates of the memory cells MC<0> to <N−1> are connected to the word lines WL<0> to <N−1>. Gates of the source-side selection gate transistor STS and the drain-side selection gate transistor STD are connected to the source-side selection gate line SGS and the drain-side selection gate line SGD.

In the above configuration, the M memory strings MS arranged in the row direction configure one memory block MB. This memory block MB serves as a unit of batch erasure of data. The memory cell array 1 includes L memory blocks MB<0> to <L−1> arranged in the column direction.

The word lines WL, the source-side selection gate line SGS, and the drain-side SGL are driven by the row decoder 2a. The bit lines BL are respectively connected to sense amplifier circuits S/A of the page buffer 3.

Next, a structure of the memory cell array 1 will be described.

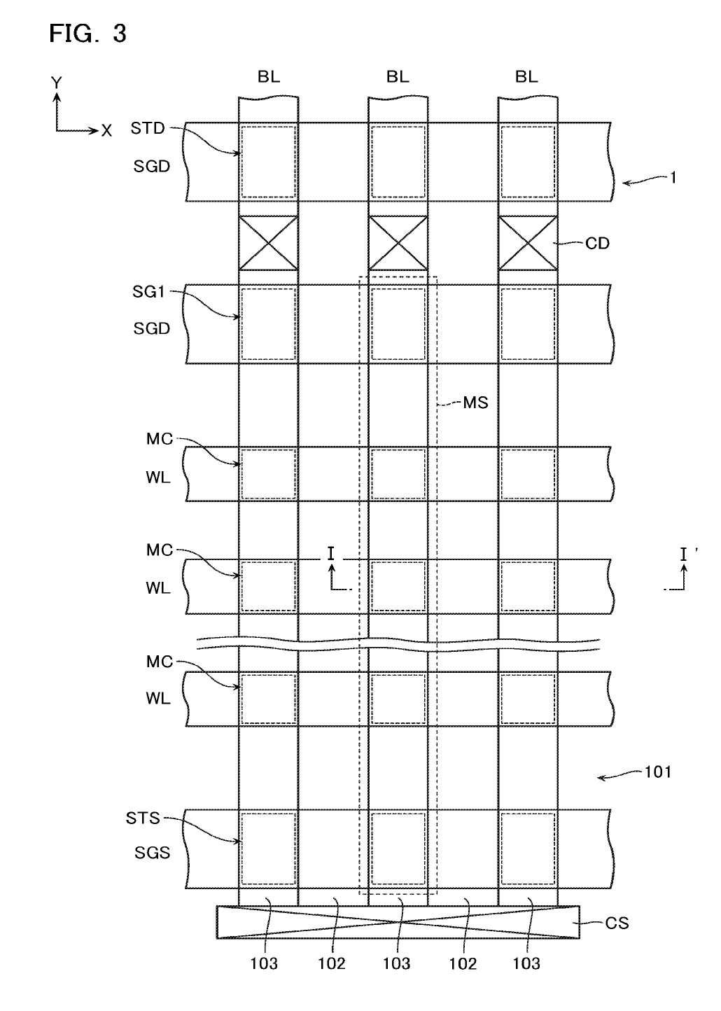

FIG. 3 is a plan view of a part of a memory cell array of a semiconductor memory device according to the present embodiment.

The memory cell array 1 includes the plurality of word lines WL extending in an X direction that is the row direction, the plurality of bit lines BL extending in a Y direction that is the column direction, and the memory cells MC arranged in respective intersections of the plurality of word lines WL and the plurality of bit lines BL.

The source-side selection gate transistor STS, the plurality of memory cells MC, and the drain-side selection gate transistor STD arranged in the Y direction are connected in series and configure one memory string MS. As described below, a semiconductor substrate 101 on which the memory cells MC are formed is separated into a plurality of active areas 103 with element isolation insulating layers 102 formed having the Y direction as a longitudinal direction. The memory string MS is formed along the active area 103. A plurality of the memory strings MS arranged in the X direction is commonly connected to the same word line WL to form one memory block MB. The memory block MB is a minimum unit of a data erasure operation. Note that one or more dummy cells that are not used for data storage can be arranged at least one of between the source-side selection gate transistor STS and the memory cells MC, and between the memory cells MC and the drain-side selection gate transistor STD, of the memory string MS.

The source of the source-side selection gate transistor STS of the memory string MS is connected to the source line SL (not illustrated in FIG. 2) through a source-side contact CS. Further, the gate of the source-side selection gate transistor STS is connected to the source-side selection gate line SGS extending in the X direction. Meanwhile, the drain of the drain-side selection gate transistor STD of the memory string MS is connected to the bit line BL through a drain-side contact CD. Further, the gate of the drain-side selection gate transistor STD is connected to the drain-side selection gate line SGD extending in the X direction.

Next, a memory cell MC′ of a comparative example will be described before describing the structure of the memory cell MC. Note that a memory cell array of the comparative example will be written as memory cell array 300 to be distinguished from the embodiment.

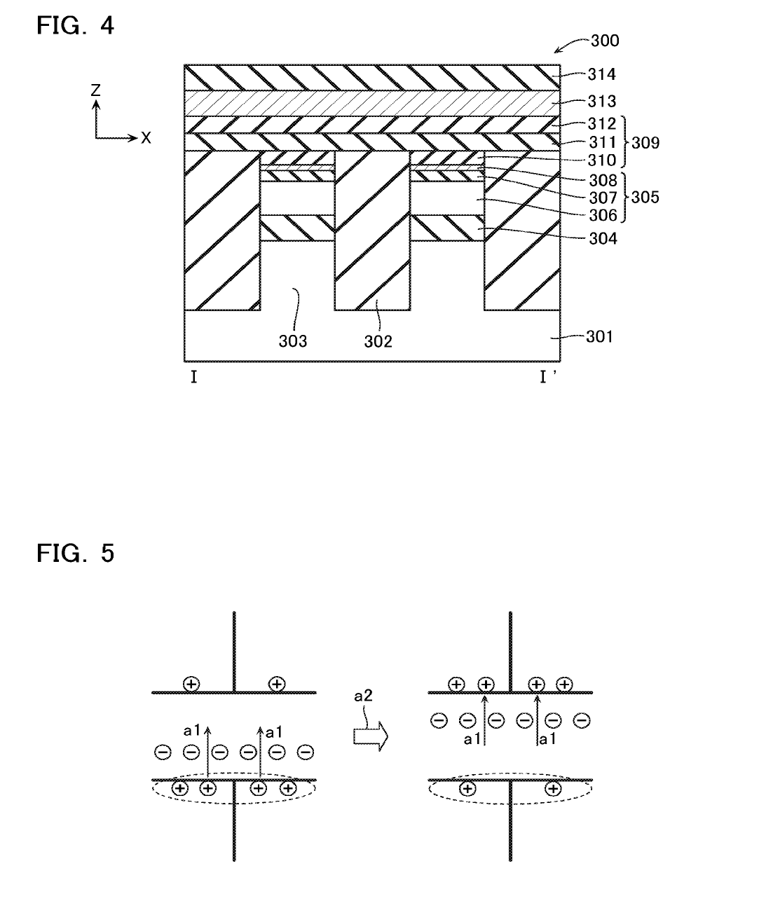

FIG. 4 is a sectional view of a part of a memory cell array of a semiconductor memory device according to the comparative example of the present embodiment. FIG. 4 is a sectional view of the comparative example corresponding to an I-I′ sectional view of FIG. 3.

A plurality of memory cells MC′ is arranged on a semiconductor substrate 301. A plurality of element isolation insulating layers 302 extending in the Y direction is arranged on a surface of the semiconductor substrate 301 at predetermined intervals in the X direction. Here, the element isolation insulating layer 302 is made of silicon oxide (SiO₂). An area of the semiconductor substrate 301 sandwiched by the element isolation insulating layers 302 is an active area 303. The active areas 303 extend in the Y direction and are arranged at predetermined intervals in the X direction, similarly to the element isolation insulating layers 302.

Each memory cell MC′ includes a tunnel insulating layer 304 arranged above the active areas 303, a charge accumulation layer 305 arranged above the tunnel insulating layer 304, a block insulating layer 309 arranged above the charge accumulation layer 305, a control gate 313 arranged above the block insulating layer 309, and an interlayer insulating layer 314 arranged above the control gate 313.

The charge accumulation layer 305 includes a semiconductor layer 306 arranged above the tunnel insulating layer 304, an inter floating gate dielectric (IFD) film 307 arranged above the semiconductor layer 306, and a metal film 308 arranged above the IFD film 307. Here, the semiconductor layer 306 is made of polysilicon (poly-Si). The IFD film 307 is made of silicon nitride (Si₃N₄). The IFD film 307 electrically insulates the semiconductor layer 306 and the metal film 308.

The block insulating layer 309 includes a lower block insulating film 310 arranged above the metal film 308, an intermediate block insulating film 311 arranged above the lower block insulating film 310, and an upper block insulating film 312 arranged above the intermediate block insulating film 311. Here, the lower block insulating film 310 and the upper block insulating film 312 are high dielectric constant insulating films. The intermediate block insulating film 311 is made of silicon oxide (SiO₂). Further, the intermediate block insulating film 311 and the upper block insulating film 312 are continuously formed on the active areas 303 arranged in the X direction, similarly to the control gate 313.

The control gate 313 is made of tungsten (W). The control gate 313 also functions as the word line WL.

The interlayer insulating layer 314 is made of silicon oxide (SiO₂).

The memory cell MC′ having the above structure has problems like below.

FIG. 5 is a diagram for describing a variation mechanism of a threshold voltage of a memory cell of a semiconductor memory device according to the present comparative example.

The block insulating layer 309 of the memory cell MC′ inherently contains metal oxide with charges that are less easily trapped. However, in the case of the memory cell MC′, the material of the metal film 308 and the material of the block insulating layer 309 have high affinity, in addition to the fact that the metal film 308 and the block insulating layer 309 are physically in contact. Therefore, atoms of the metal film 308 are diffused in the block insulating layer 309 by thermal treatment in a process of forming the memory cell MC′ (the arrows a1 in FIG. 5). As a result, the charges are more easily trapped in the block insulating layer 309 (the arrow a2 in FIG. 5). However, the block insulating layer 309 itself cannot trap the charges for a long time, and thus the charge holding property of the memory cell MC′ becomes worse.

Therefore, in the present embodiment, a memory cell MC having a structure like below is used.

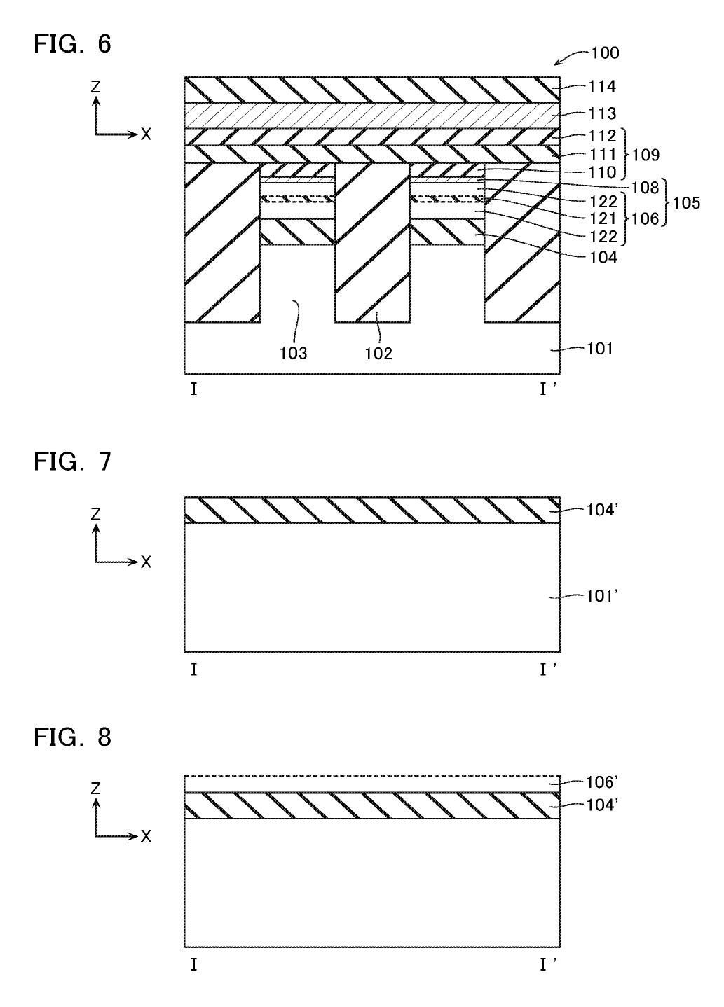

FIG. 6 is a sectional view of a part of a memory cell array of a semiconductor memory device according to the present embodiment. FIG. 6 is an I-I′ sectional view of FIG. 3.

The plurality of memory cells MC is arranged above the semiconductor substrate 101 (first semiconductor layer). The plurality of element isolation insulating layers 102 extending in the Y direction is arranged on the surface of the semiconductor substrate 101 at predetermined intervals in the X direction. Here, the element isolation insulating layer 102 is made of silicon oxide (SiO₂). The area of the semiconductor substrate 101 sandwiched by the element isolation insulating layers 102 is the active area 103. The active areas 103 extend in the Y direction, and are arranged in the X direction at predetermined intervals, similarly to the element isolation insulating layer 102.

Each memory cell MC includes a tunnel insulating layer 104 arranged above the active areas 103, a charge accumulation layer 105 arranged above the tunnel insulating layer 104, a block insulating layer 109 arranged above the charge accumulation layer 105, a control gate 113 arranged above the block insulating layer 109, and an interlayer insulating layer 114 arranged above the control gate 113.

The charge accumulation layer 105 includes a semiconductor layer 106 (second semiconductor layer) arranged above the tunnel insulating layer 104, and a metal film 108 arranged above the semiconductor layer 106. The semiconductor layer 106 includes a dividing film 121 and divided portions 122 divided by the dividing film 121.

The block insulating layer 109 includes a lower block insulating film 110 arranged above the metal film 108, an intermediate block insulating film 111 arranged above the lower block insulating film 110, and an upper block insulating film 112 arranged above the intermediate block insulating film 111. Here, the lower block insulating film 110 and the upper block insulating film 112 are so-called high dielectric constant insulating films made of hafnium oxide (HfO₂), aluminum oxide (Al₂O₃), titanium oxide (TiO₂), tantalum oxide (Ta₂O₅), hafnium silicate (HfSiO₄), or hafnium nitride silicate (HfSiON). The intermediate block insulating film 111 is made of silicon oxide (SiO₂), for example. In the case of FIG. 6, the intermediate block insulating film ill and the upper block insulating film 112 are continuously formed above the active areas 103 arranged in the X direction, similarly to the control gate 113. However, the present embodiment is not limited to the case. Further, in the case of FIG. 6, the block insulating layer 109 is configured from three block insulating films 110 to 112. However, the present embodiment is not limited to the case, and the block insulating layer 109 can be configured from a single, two, or four or more block insulating films.

The control gate 113 is made of tungsten (W), for example. The control gate 113 also functions as the word line WL.

The interlayer insulating layer 114 is made of silicon oxide (SiO₂), for example.

In the case of the memory cell MC of the present embodiment, the memory cell MC does not have a configuration of the IFD film 307 in the charge accumulation layer 105, unlike the memory cell MC′ of the comparative example, and the semiconductor layer 106 (divided portion 122) and the metal film 108 are physically in contact. In this case, affinity between polysilicon (poly-Si) that is the material of the semiconductor layer 106 and the material of the metal film 108 is higher than the affinity of the material of the metal film 108 and the material of the block insulating layer 109. Therefore, atoms of the metal film 108 are not diffused in the block insulating layer 109, and are diffused in the semiconductor layer 106. As a result, deterioration of the block insulating layer 109 is suppressed.

Further, in the case of the memory cell MC, the dividing film 121 is arranged in the semiconductor layer 106. In this case, the upper-side divided portion 122 functions as a charge accumulation layer, and the upper-side divided portion 122 functions as a gettering layer for prevention of diffusion of metal material. Further, the dividing film 121 serves as a substitute for the IFD film 307. Therefore, the charge accumulation layer 105 can be made thinner by the IFD film 307 than the charge accumulation layer 305 of the comparative example.

Next, a method of manufacturing the memory cell array 100 will be described.

FIGS. 7 to 13 are sectional views for describing a processing manufacturing a memory cell array of a semiconductor memory device according to the present embodiment. FIGS. 7 to 13 are I-I′ sectional views of FIG. 3.

First, as illustrated in FIG. 7, an insulating layer 104′ that is to serve as the tunnel insulating layer 104 is deposited above a semiconductor substrate 101′ that is to serve as the semiconductor substrate 101 by a CVD method or the like. Here, the insulating layer 104′ is made of silicon oxide (SiO₂), for example.

Following that, as illustrated in FIG. 8, the material of the semiconductor layer 106 is deposited above the insulating layer 104′ up to the position where the dividing film 121 is arranged by the CVD method or the like. Here, the material of the semiconductor layer 106 is polysilicon (poly-Si), for example.

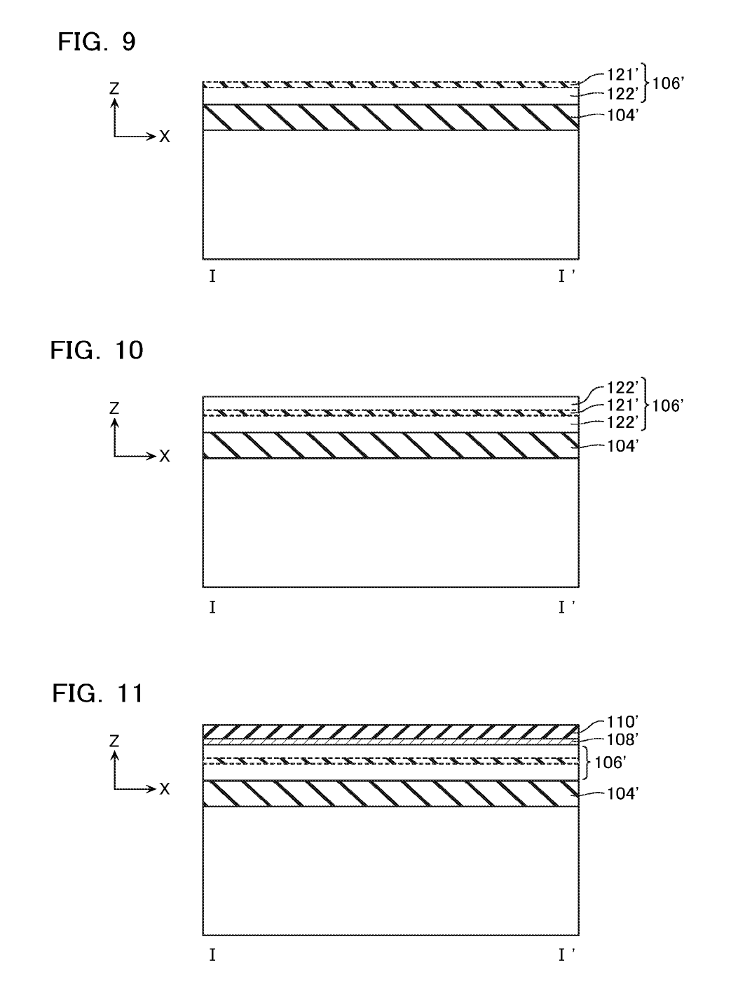

Following that, as illustrated in FIG. 9, an upper portion of the deposited material of the semiconductor layer 106 is oxidized, nitridized, or oxynitridized. By the process of FIG. 9, an insulating film 121′ that is to serve as the dividing film 121 and a semiconductor portion 122′ that is to serve as the divided portion 122 are formed.

Following that, as illustrated in FIG. 10, the material of the semiconductor layer 106 is further deposited above the insulating film 121′ by the CVD method or the like. By the process of FIGS. 8 to 10, a semiconductor layer 106′ made of the insulating film 121′ and the semiconductor portion 122′ is formed.

Following that, as illustrated in FIG. 11, a metal film 108′ that is to serve as the metal film 108 and an insulating film 110′ that is to serve as the lower block insulating film 110 are sequentially deposited above the semiconductor layer 106′ by the CVD method or the like. Here, the insulating film 110′ is made of, for example, hafnium oxide (HfO₂), aluminum oxide (Al₂O₃), titanium oxide (TiO₂), tantalum oxide (Ta₂O₅), hafnium silicate (HfSiO₄), or hafnium nitride silicate (HfSiON).

Following that, as illustrated in FIG. 12, trenches 131 extending in the Y direction are formed in the semiconductor substrate 101′, the insulating layer 104′, the semiconductor layer 106′, the metal film 108′, and the insulating film 110′ at predetermined intervals in the X direction. By this process, the semiconductor substrate 101, the tunnel insulating layer 104, the charge accumulation layer 105 made of the semiconductor layer 106 and the metal film 108, and the lower block insulating film 110 are formed.

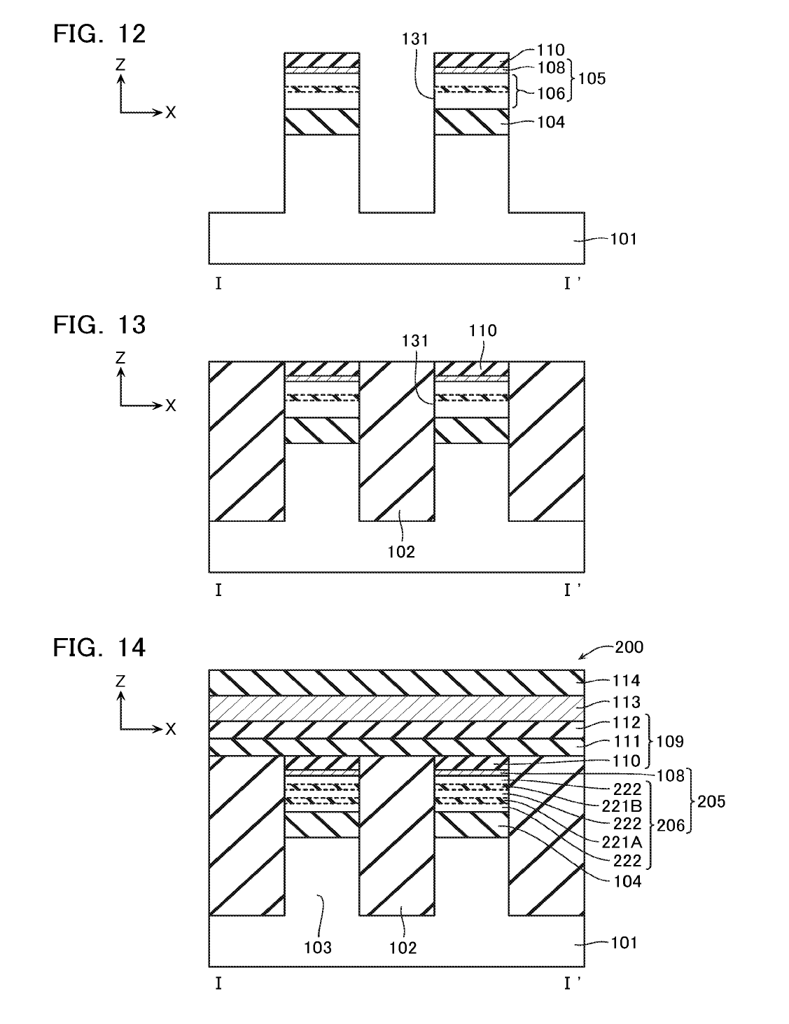

Following that, as illustrated in FIG. 13, the element isolation insulating layers 102 are embedded in the trenches 131. Here, the element isolation insulating layers 102 are made of silicon oxide (SiO₂), for example. Following that, upper surfaces of the embedded element isolation insulating layers 102 are polished by a CMP method or the like until the upper surfaces of the embedded element isolation insulating layers 102 become approximately the same as the upper surface of the lower block insulating film 110.

Finally, the intermediate block insulating film 111, the upper block insulating film 112, the control gate 113, and the interlayer insulating layer 114 are sequentially deposited above the element isolation insulating layer 102 and the lower block insulating film 110 by the CVD method. Here, the intermediate block insulating film 111 is made of silicon oxide (SiO₂), for example. The upper block insulating film 112 is made of hafnium oxide (HfO₂), aluminum oxide (Al₂O₃), titanium oxide (TiO₂), tantalum oxide (Ta₂O₅), hafnium silicate (HfSiO₄), or hafnium nitride silicate (HfSiON), for example. The control gate 113 is made of tungsten (W), for example. The interlayer insulating layer 114 is made of silicon oxide (SiO₂), for example.

The above is a part of the process of manufacturing the memory cell array 100.

According to the above-described method of manufacturing the memory cell array 100, not only a process of forming the IFD film 307 can be omitted, but also the process of forming the semiconductor layer 106′ of FIGS. 8 to 10 can be executed in-situ, which is different from the comparative example. Therefore, the process of manufacturing the memory cell array 100 can be simplified, compared with the comparative example.

According to the present embodiment, the dividing film that can be the substitute for the IFD film is formed above the semiconductor layer, and the semiconductor layer and the metal film are physically brought in contact, whereby the semiconductor memory device that realizes suppression of deterioration of the block insulating layer, the thin charge accumulation layer, and simplification of the process of manufacturing the memory cell array can be provided.

### Second Embodiment

A second embodiment is a modification of the first embodiment. Here, different points from the first embodiment will be mainly described. Note that, hereinafter, a memory cell array 1 of the present embodiment will be described as memory cell array 200 to be distinguished from other embodiments and the comparative example.

First, a structure of the memory cell array 200 of the present embodiment will be described.

FIG. 14 is a sectional view of a part of a memory cell array of a semiconductor memory device according to the present embodiment. FIG. 14 is an I-I′ sectional view of FIG. 3. Note that a configuration similar to the configuration illustrated in FIG. 6 is denoted with the same reference sign as FIG. 6.

In the case of a memory cell MC of the memory cell array 200, a configuration of a semiconductor layer 206 of a charge accumulation layer 205 is different from the memory cell MC of the memory cell array 100. To be specific, the semiconductor layer 206 of the memory cell array 200 includes a plurality of dividing films 221 (221A and 221B in the case of FIG. 6), and divided portions 222 divided by the plurality of dividing films 221.

Next, a method of manufacturing the memory cell array 200 will be described.

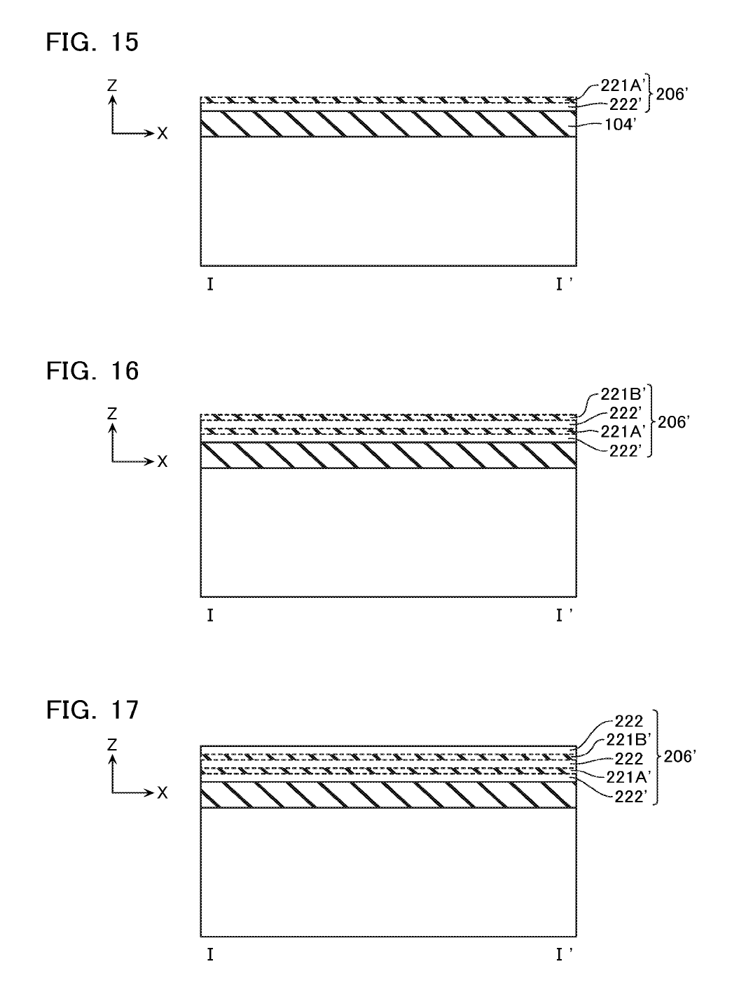

FIGS. 15 to 17 are sectional views for describing a process of manufacturing a memory cell array of a semiconductor memory device according to the present embodiment. FIGS. 15 to 17 are I-I′ sectional views of FIG. 3.

First, a process similar to the process of FIG. 7 is executed.

Following that, as illustrated in FIG. 15, a material of the semiconductor layer 206 is deposited above an insulating layer 104′ that is to serve as a tunnel insulating layer 104 by a CVD method or the like up to the position where the first dividing film 221A is arranged. Following that, an upper portion of the material of the deposited semiconductor layer 206 is oxidized, nitridized, or oxynitridized. By this process, an insulating film 221A′ that is to serve as the dividing film 221A, and a lower-side semiconductor portion 222′ that is to serve as the divided portion 222 are formed.

Following that, as illustrated in FIG. 16, the material of the semiconductor layer 206 is deposited above the insulating film 221A′ by the CVD method or the like up to the position where the second dividing film 221B is arranged. Following that, an upper portion of the material of the deposited semiconductor layer 206 is oxidized, nitridized, or oxynitridized. By this process, an insulating film 221B′ that is to serve as the dividing film 221B and an intermediate portion of the semiconductor portion 222′ that is to serve as the divided portion 222 are formed.

Following that, as illustrated in FIG. 17, the material of the semiconductor layer 206 is further deposited above the insulating film 221A′ by the CVD method or the like. By the process of FIGS. 15 to 17, a semiconductor layer 206′ made of the insulating films 221A′ and 221B′, and the semiconductor portion 222′ is formed. Note that the process of FIGS. 15 to 17 is a case where the two dividing films 221A and 221B are included in the semiconductor layer 206. However, when three or more dividing films 221 are included in the semiconductor layer 206, a process similar to the process of FIG. 16 is repeatedly executed according to the number.

Following that, a process similar to the process of FIGS. 11 to 13 is executed.

The above is a part of the process of manufacturing the memory cell array 200.

In the case of the first embodiment, only one dividing film 121 is formed in the semiconductor layer 106, and thus an excess reaction of the material of the semiconductor layer 106 and the material of the metal film 108 may not be able to be suppressed. In this regard, according to the second embodiment, the plurality of dividing films 221 is formed in the semiconductor layer 206, and thus the above reaction can be appropriately suppressed. It is desirable to form the dividing films 221 in the semiconductor layer 206 by an appropriate number within a range of an allowable film thickness of the semiconductor layer 206.

### [Others]

Some embodiments of the present invention have been described. However, these embodiments have been exemplarily described, and are not intended to limit the scope of the invention. These new embodiments can be implemented in other various forms, and various omissions, replacements, and changes can be performed without departing from the gist of the invention. These embodiments and its modifications are included in the scope or the gist of the invention, and are included in the invention described in claims and its equivalents.

What is claimed is:

1. A semiconductor memory device comprising:
a tunnel insulating layer arranged above a first semiconductor layer;
a charge accumulation layer arranged above the tunnel insulating layer;
a block insulating layer arranged above the charge accumulation layer; and
a control gate arranged above the block insulating layer,
the charge accumulation layer including a second semiconductor layer, and a metal film arranged above the second semiconductor layer, and
the second semiconductor layer including a dividing film made of an insulator, and a divided portion divided by the dividing film.

2. The semiconductor memory device according to claim 1, wherein the metal film is physically in contact with the second semiconductor layer.

3. The semiconductor memory device according to claim 1, wherein the metal film is physically in contact with the divided portion of the second semiconductor layer.

4. The semiconductor memory device according to claim 1, wherein the second semiconductor layer includes a plurality of the dividing films.

5. The semiconductor memory device according to claim 1, wherein the dividing film of the second semiconductor layer is an oxide film, a nitride film, or an oxynitride film.

6. The semiconductor memory device according to claim 1, wherein the second semiconductor layer contains silicon (Si).

7. A method of manufacturing a semiconductor memory device, the method comprising:
forming a tunnel insulating layer above a first semiconductor layer;
forming a charge accumulation layer above the tunnel insulating layer;
forming a block insulating layer above the charge accumulation layer;
forming a control gate above the block insulating layer;
forming a second semiconductor layer above the tunnel insulating layer when forming the charge accumulation layer;
forming a metal film above the second semiconductor layer; and
forming a dividing film made of an insulator in the second semiconductor layer and a divided portion divided by the dividing film when forming the second semiconductor layer.

8. The method of manufacturing a semiconductor memory device according to claim 7, comprising:
forming the metal film physically in contact with the second semiconductor layer.

9. The method of manufacturing a semiconductor memory device according to claim 7, comprising:
forming the metal film physically in contact with the divided portion of the second semiconductor layer.

10. The method of manufacturing a semiconductor memory device according to claim 7, comprising:
forming a plurality of the dividing films in the second semiconductor layer when forming the second semiconductor layer.

11. The method of manufacturing a semiconductor memory device according to claim 7, comprising:
oxidizing, nitridizing, or oxynitridizing a material of the second semiconductor layer to form the dividing film when forming the second semiconductor layer.

12. The method of manufacturing a semiconductor memory device according to claim 7, comprising:
forming the second semiconductor layer, using silicon (Si).
